(19) United States
(12) Patent Application Publication
(10) Pub. No.: US 2026/0363057 A1
(43) Pub. Date: Nov. 12, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Chia-Pang KUO, Taoyuan (TW); Yen-Chun LIN, Hsinchu (TW); Kai-Shiang KUO, Hsinchu (TW); Cheng-Hui WENG, Hsinchu (TW)

(73) Assignee: Taiwan Semiconductor Manufacturing Company, Ltd., Hsinchu (TW)

(21) Appl. No.: 19/422,243

(22) Filed: Dec. 16, 2025

Related U.S. Application Data
(60) Provisional application No. 63/804,285, filed on May 12, 2025.

(51) Int. Cl. H10W 20/41; H10P 52/40; H10W 20/00; H10W 20/40; H10W 20/44

(52) U.S. Cl. CPC H10W 20/438; H10P 52/403; H10W 20/057; H10W 20/062; H10W 20/435; H10W 20/4421; H10W 20/4441; H10W 20/498

(57) ABSTRACT

A method of manufacturing a semiconductor device includes forming a first metal layer in a dielectric layer including a first metal in a first trench and in a second trench, wherein the second trench is narrower than the first trench, and a first thickness of the first metal layer in the first trench is different from a second thickness of the first metal layer in the second trench. A second metal layer including a second metal is formed over the first metal layer. A polishing process is performed to the first and second metal layers to form a first metal line in the first trench and form a second metal line in the second trench. The first metal line and the second metal line are spaced apart from one another by the dielectric layer.

### RELATED APPLICATION

This application claims priority to U.S. Provisional Application No. 63/804,285 filed May 12, 2025, the entire disclosure of which is incorporated herein by reference.

### BACKGROUND

As consumer devices with ever better performance have gotten smaller and smaller in response to consumer demand, the individual components of these devices have necessarily decreased in size as well. Semiconductor devices, which make up major components of consumer devices such as mobile phones, computer tablets, and the like, have become smaller and smaller. The decrease in size of semiconductor devices has been met with advancements in semiconductor manufacturing techniques such as forming connections between semiconductor devices. As device size decreases, resistance in smaller connections increases along with a corresponding increase in heating of the device circuitry. Lower resistance connections are desirable in smaller devices. Lower resistance means less energy is lost as heat when electricity flows through the circuitry, resulting in more efficient operation.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A shows a cross-sectional view of a stage of a method of manufacturing a semiconductor device according to embodiments of the disclosure. FIG. 1B shows a detailed view of a semiconductor device component.

FIG. 2 shows a cross-sectional view of a stage of a method of manufacturing a semiconductor device according to embodiments of the disclosure.

FIGS. 3, 4A, 4B, 5, 6, and 7 show cross-sectional views of stages of a method of manufacturing a semiconductor device according to embodiments of the disclosure.

FIGS. 8, 9, and 10 show detailed cross-sectional views of stages of a method of manufacturing a semiconductor device according to embodiments of the disclosure.

FIG. 11A shows a plan view of a semiconductor device according to embodiments of the disclosure. FIGS. 11B, 11C, and 11D show various cross-sectional views of the semiconductor device of FIG. 11A.

FIGS. 12, 13, 14A, 14B, 15A, 15B, 16A, and 16B show detailed cross-sectional views of stages of a method of manufacturing a semiconductor device according to embodiments of the disclosure.

FIGS. 17A, 17B, 17C, and 17D show detailed cross-sectional views of stages of a method of manufacturing a semiconductor device according to embodiments of the disclosure.

FIGS. 18A, 18B, 18C, and 18D show detailed cross-sectional views of stages of a method of manufacturing a semiconductor device according to embodiments of the disclosure.

FIGS. 19A, 19B, 19C, 19D, 19E, 19F, 19G, 19H, 19I, 19J, and 19K show cross-sectional views of stages of a method of manufacturing a semiconductor device according to embodiments of the disclosure. FIG. 19L shows a plan view of semiconductor device according to embodiments of the disclosure.

FIG. 20A shows the a graph of the line width versus line resistance of metal lines according to embodiments of the disclosure. FIG. 20B shows a narrow metal line according to an embodiment of the disclosure. FIG. 20C shows a wide metal line according to an embodiment of the disclosure.

FIGS. 21A, 21B, and 21C show cross-sectional views of stages of a method of manufacturing a semiconductor device according to embodiments of the disclosure.

FIG. 22 shows a flow chart for a method according to embodiments of the present disclosure.

FIG. 23 shows a flow chart for a method of manufacturing a semiconductor device according to embodiments of the present disclosure.

FIG. 24 shows a flow chart for a method of manufacturing a semiconductor device according to embodiments of the present disclosure.

### DETAILED DESCRIPTION

It is to be understood that the following disclosure provides many different embodiments, or examples, for implementing different features of the disclosure. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.”

Further, in the following fabrication process, there may be one or more additional operations in between the described operations, and the order of operations may be changed. In the present disclosure, a phrase “one of A, B and C” means “A, B and/or C” (A, B, C, A and B, A and C, B and C, or A, B and C), and does not mean one element from A, one element from B and one element from C, unless otherwise described. In the entire disclosure, a source and a drain are interchangeably used, and a source/drain refers to one of or both of the source and the drain. Source/drain structure(s) may refer to a source or a drain, individually or collectively dependent upon the context. In the following embodiments, materials, configurations, dimensions, processes and/or operations as described with respect to one embodiment (e.g., one or more figures) may be employed in the other embodiments, and detailed description thereof may be omitted.

Disclosed embodiments relate to a semiconductor device, in particular, to a semiconductor device having lower resistance and lower resistance capacitance (RC) conductive lines or wirings, and their manufacturing methods.

As semiconductor devices are scaled down in size, the space for the electrical connections between the front end of the line (FEOL) devices and back end of the line (BEOL) wiring layers becomes smaller, which increases the contact resistance of the electrical connections. In embodiments of the disclosure, a low resistance and lower RC connection is provided. Thus, semiconductor devices that can operate at higher power with increased efficiency are provided by embodiments of the present disclosure.

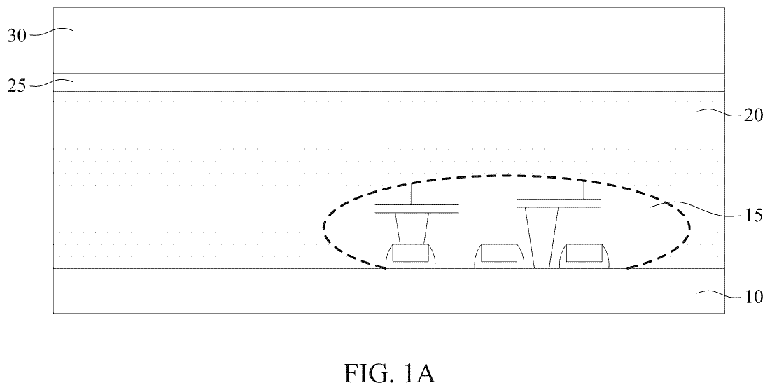

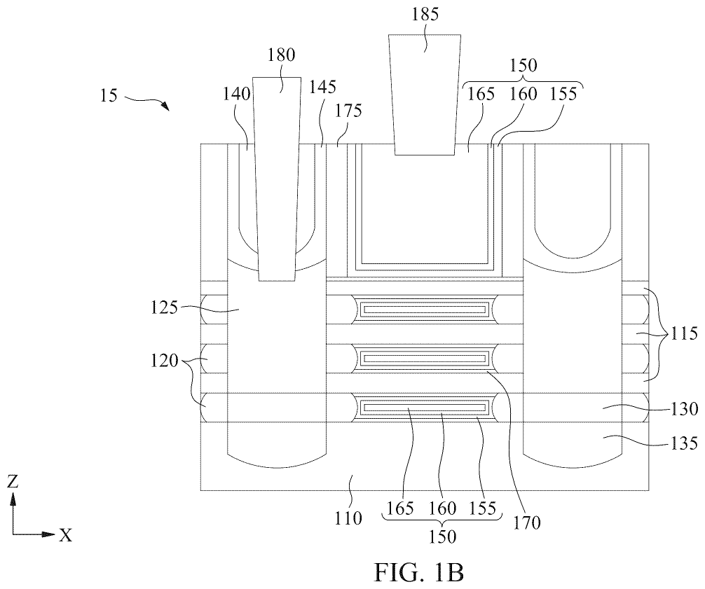

A semiconductor device structure according to embodiments of the disclosure is illustrated in FIG. 1A. The structure includes a first dielectric layer 30 formed over a device region 20 disposed over a substrate 10. In some embodiments, the device region 20 includes one or more semiconductor device components or integrated circuit components, such as transistors 15. In some embodiments, an etch stop layer 25 is disposed between the dielectric layer 30 and the device region 20.

In some embodiments, the transistor 15 is a gate-all-around (GAA) or nanosheet field effect transistor (FET), however the present disclosure is not limited to GAA FET. The transistor may be a fin field effect transistor (FinFET), a planar transistor, a complementary FET (CFET), forked sheet transistor, or any other suitable transistor. An example of a GAA FET 15 is illustrated in FIG. 1B. The GAA FET 15 includes a gate structure 150 disposed around a stack of semiconductor channel layers 115 in some embodiments. The gate structure 150 includes a gate dielectric layers 155 disposed over the channel layers 115 and a gate electrode layer 165 disposed over the gate dielectric layer 155. In some embodiments, one or more work function adjustment layers 160 are disposed between the gate dielectric layer 155 and the gate electrode layer 165. Source/drain regions 125 are disposed on opposing sides of the gate electrode structure 150. Insulating inner spacers 120 are disposed between the gate structure 150 and the source/drain regions 125. In some embodiments, an interfacial layer 170 is disposed between the channel layers 115 and the gate dielectric layer 155. Insulating gate sidewall spacers 175 are on sidewalls of the gate structure 150 in some embodiments. In some embodiments, a source/drain contact 180 is electrically coupled to the source/drain region 125, and a gate contact 185 is electrically coupled to the gate electrode layer 165. In some embodiments, a interlayer dielectric layer 140 and an etch stop layer 145 are disposed over the source/drain region 125, and the source/drain contact 180 passes through the interlayer dielectric layer 140 and etch stop layer 145. In some embodiments a bottom semiconductor layer 135 is formed in the substrate 110 spaced apart from the source/drain region 125 by a flexible bottom isolation layer 130.

An interconnect structure is formed over the device region 20, and is electrically connected to the transistors 15 in the device region 20. The interconnect structure includes one or more dielectric layers, metal lines, and vias. For example, the interconnect structure includes the etch stop layer 25 and the first dielectric layer 30. The interconnect structure includes pattern (line) layers having conductive patterns interconnecting various features in one portion of the die to other features of the die. The interconnect structures are formed of conductive materials such as metal and the semiconductor devices include several interconnect layers in various embodiments. The interconnect layers are often referred to as “metal 0” or “M0” (designating the lowermost interconnect level), “M1,” “M2,” and so on. These designations are used in the art to indicate that the conductive lines interconnect features from various locations in the semiconductor device. In some embodiments, the metal interconnect lines connect an array of transistors to other arrays or other features.

The interconnect layer patterns in different layers are also coupled to one another through vias that extend vertically between one or several interconnect layers. The interconnect layer patterns are coupled to external features and can represent bit lines, signal lines, word lines, and various input/output connections in some embodiments.

Examples of devices that can benefit from one or more embodiments of the present disclosure are semiconductor devices. Such a device, for example, may include static random access memory (SRAM) and/or other logic circuits, passive components such as resistors, capacitors, and inductors, and active components such as P-channel field effect transistors (PFET), N-channel FET (NFET), metal-oxide semiconductor field effect transistors (MOSFET), complementary metal-oxide semiconductor (CMOS) transistors, such as FinFETs and GAA FETs, bipolar transistors, high voltage transistors, high frequency transistors, other memory cells, and combinations thereof. The semiconductor device may include a plurality of semiconductor devices (e.g., transistors), which may be interconnected. In some embodiments, the semiconductor device components are electrically coupled through underlying interconnection layers including wiring layers and vias formed in dielectric layers, such as an interlayer dielectric (ILD) layer or an intermetal dielectric (IMD) layer. The wiring layers and vias of the interconnection layer may be formed of copper or copper alloys (e.g., AlCu), aluminum, tungsten, nickel, ruthenium, cobalt, molybdenum, or any other suitable metal. It is understood, however, that the application should not be limited to a particular type of device, except as specifically claimed.

In some embodiments, the substrate 10 includes a single crystalline semiconductor layer on at least its surface portion. The substrate 10 may include a single crystalline semiconductor material such as, but not limited to Si, Ge, SiGe, GaAs, InSb, GaP, GaSb, InAlAs, InGaAs, GaSbP, GaAsSb, and InP. The substrate 10 may include various regions that have been suitably doped with impurities (e.g., p-type or n-type conductivity). The dopants are, for example, boron difluoride (BF₂) for an n-type Fin FET and phosphorus for a p-type Fin FET in some embodiments. In certain embodiments, the substrate 10 is made of crystalline Si.

The substrate 10 may include in its surface region, one or more buffer layers (not shown). The buffer layers can serve to gradually change the lattice constant from that of the substrate to that of the source/drain structures. The buffer layers may be formed from epitaxially grown single crystalline semiconductor materials such as, but not limited to Si, Ge, GeSn, SiGe, GaAs, InSb, GaP, GaSb, InAlAs, InGaAs, GaSbP, GaAsSb, GaN, GaP, and InP. In a particular embodiment, the substrate 10 includes silicon germanium (SiGe) buffer layers epitaxially grown on the silicon substrate 10. The germanium concentration of the SiGe buffer layers may increase from 30 atomic % germanium for the bottom-most buffer layer to 70 atomic % germanium for the top-most buffer layer.

In some embodiments, the dielectric layer 30 is made of a silicon oxide, a silicon nitride, a silicon oxynitride (SiON), SiOCN, SiCN, a fluorine-doped silicate glass (FSG), or a low-k dielectric material, formed by chemical vapor deposition (CVD) including low pressure CVD deposition (LPCVD), plasma-enhanced CVD (PECVD), physical vapor deposition (PVD), atomic layer deposition (ALD,) flowable CVD, or any suitable technique.

In some embodiments, the etch stop layer 25 is made of a nitride, such as a silicon nitride, a titanium nitride, or a tantalum nitride. The etch stop layer 65 may be formed by ALD, PVD, CVD, e-beam evaporation, or any other suitable technique. In some embodiments, the etch stop layer 25 has a thickness ranging from about 5 nm to about 40 nm, and from about 10 nm to about 20 nm in other embodiments. In some embodiments, the etch stop layer 25 and the dielectric layer 30 are made of different materials.

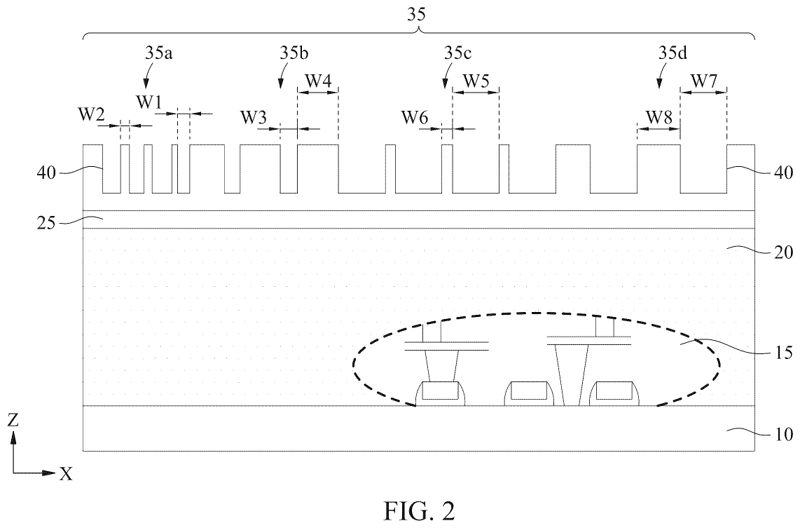

The dielectric layer 30 is patterned to form a patterned layer 35, as shown in FIG. 2. In some embodiments, the patterned dielectric layer 35 is formed using photolithographic and etching operations. In some embodiments, various different pattern areas 35a, 35b, 35c, 35d are formed in the patterned dielectric layer 35. For example, a first pattern area 35a may include a dense concentration of narrow trenches 40 having a first width W1 separated by dielectric layer regions having a second width W2 less than the first width W1. A second pattern area 35b may include trenches 40 having a third width W3 separated by dielectric layer regions having a fourth width W4 greater than the third width W3. The third width W3 of the trenches in the second pattern may be about the same as the first width W1 of the trenches in the first pattern area 35a. A third pattern area 35C may include a dense concentration of wide trenches 40 having a fifth width W5 separated by dielectric layer regions having a sixth width W6 less than the fifth width. The sixth width W6 may be about the same width as the second width W2. A fourth pattern area 35d may include trenches 40 having a seventh width W7 separated by a dielectric layer region having an eighth width W8 less than the seventh width W7 and greater than the sixth width W6. The seventh width W7 may be about the same as the fifth width W5 and the eighth width W8 may be about the same as the fourth width W4.

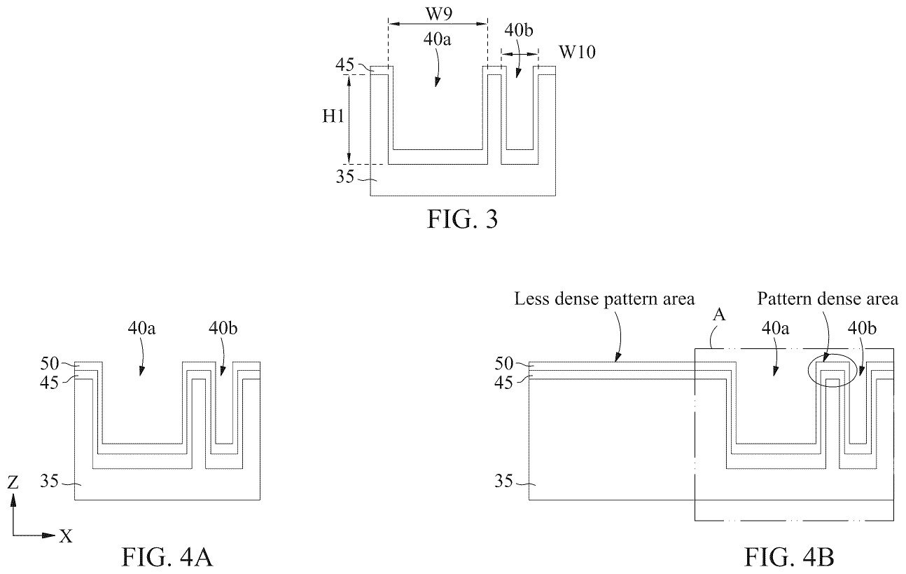

FIGS. 3-7 show cross-sectional views of stages of a method of manufacturing a semiconductor device according to embodiments of the disclosure. To simplify the disclosure, the semiconductor device component region 20, etch stop layer 25, and the substrate 10 are not shown in FIGS. 3-7. It is understood that additional operations can be provided before, during, and after processes shown by FIGS. 3-7, and some of the operations described below can be replaced or eliminated, for additional embodiments of the method. The order of the operations/processes may be interchangeable.

In some embodiments, a barrier layer 45 is formed over the patterned dielectric layer 35. The patterned dielectric layer 35 includes a wide trench 40a having a width W9 and a narrow trench 40b having a width W10 less than the width W9. In some embodiments, the barrier layer 45 is a metal nitride layer, such as a tantalum nitride. The barrier layer 45 may be formed by ALD, PVD, or CVD. In some embodiments, the barrier layer has a thickness ranging from about 1 nm to about 10 nm, and from about 3 nm to about 5 nm in other embodiments.

A liner layer 50 is subsequently formed over the barrier layer 45 in some embodiments, as shown in FIGS. 4A and 4B. In some embodiments, the liner layer 50 includes at least one of cobalt, ruthenium, molybdenum, or tungsten. The liner layer 50 may be deposited by ALD, PVD, CVD, e-beam evaporation, electroplating, electroless plating, or any other suitable technique. In some embodiments, the liner layer has a thickness ranging from about 1 nm to about 20 nm, and from about 3 nm to about 10 nm in other embodiments. FIG. 4B is a broader view of the detailed views A shown in FIGS. 3, 4A, 5, 6, and 7. FIG. 4B illustrates a pattern dense area of the dielectric layer and a less dense pattern area.

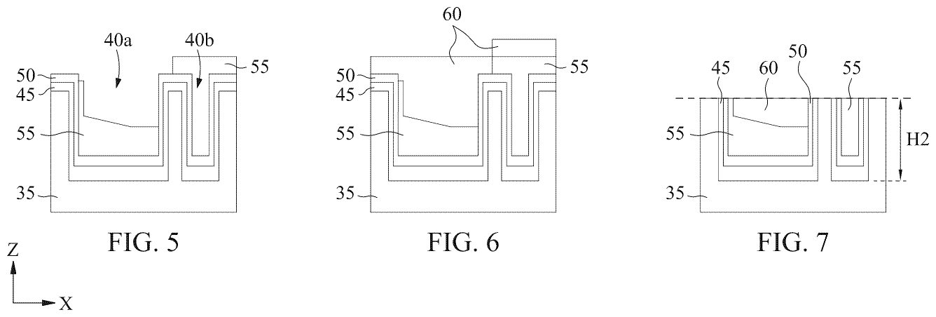

A first metal layer 55 is subsequently deposited over the liner layer 50, as shown in FIG. 5. The first metal layer may be deposited by ALD, PVD, CVD, metal-organic CVD (MOCVD), e-beam evaporation, electroplating, electroless plating, or any other suitable technique. In some embodiments, the first metal layer 55 is made of a different material than the liner layer 50, and includes at least one of ruthenium, cobalt, molybdenum, or tungsten. The first metal layer 55 fills the narrower trenches faster in the depth direction than the wider trenches in some embodiments, as shown in FIG. 5. In some embodiments, the first metal layer 55 fully fills the narrow trench 40b. In other embodiments, the second metal layer 60 fills a portion of the narrow trench 40b, and the first metal layer 55 fills a greater portion of the narrow trench 40b than the second metal layer 60.

The first metal layer 55 is subjected to a thermal reflow operation in some embodiments. In some embodiments, the thermal reflow operation is performed using infrared heating. In some embodiments, the backside of the semiconductor device structure is exposed to an infrared heating lamp. In other embodiments, the infrared radiation source is an infrared laser. During the thermal reflow, the first metal layer 55 is heated and flows by capillary effect so that first metal has a different thickness on the sidewalls of the trench 40a in a pattern dense region than a less dense pattern area. In the less dense pattern area, a larger amount of the first metal is attached to the sidewall. Less of the first metal is attached to the sidewall near the pattern dense area, as shown in FIG. 5.

Next, a second metal layer 60 is deposited over the reflowed first metal layer 55, as shown in FIG. 6. The second metal layer 60 may be made of any metal having high conductivity. In some embodiments, the second metal layer 60 is made of different metal than the first metal layer and is made of at least one of a copper or a copper alloy, ruthenium, cobalt, molybdenum, or tungsten. In some embodiments, the second metal layer 60 undergoes a thermal reflow operation as described herein. The metal conductivity is a function of temperature and line width or thickness. As the line width shrinks, the metal conductivity decreases (the resistivity increases) due to electron surface scattering and grain boundary scattering. For example, when the line width decreases from about 100 nm to about 15 nm there is a drastic change in conductivity. Therefore, some metals may have a higher conductivity (lower resistance) than other metals at a first metal layer width or thickness, and have lower conductivity (higher resistance) than the other metals at a second metal layer width or thickness. For example, Cu may have higher conductivity than Ru or Co at a first wider width or thickness, and lower conductivity than Ru or Co at a second narrower width or thickness. While a trench having a width of greater than about 15 nm and having a greater volume of Cu than Ru or Co would have lower resistivity than a trench of the same width having a greater volume of Ru or Co, in some embodiments, a trench having a having a width of less than about 15 nm and having a volume of Cu greater than Ru or Co has a higher resistivity than a trench of the same width having a greater volume of Ru or Cu. In some embodiments, a dual-layer metal filling in the trench has a greater portion of a first metal, such as Cu, in a wider metal line, and a greater portion of a second metal, such as Ru or Co in a narrower metal. The dual-layer metal lines of the present disclosure provide interconnects with overall lower resistivity than interconnects having different width metal lines made of single metal.

In an embodiment, the barrier layer 45 is made of tantalum nitride, the liner layer 50 is made of ruthenium, the first metal layer 55 is made of cobalt, and the second metal layer 60 is made of copper.

After forming the second metal layer, the semiconductor structure of FIG. 6 undergoes a chemical-mechanical polishing (CMP) to remove the metal layers overlying an uppermost surface of the patterned dielectric layer 35, as shown in FIG. 7. An upper portion of the patterned dielectric layer 35 is removed in some embodiment during the CMP operation. In some embodiments, the CMP reduces the depth of the trenches 40a, 40b from a depth H1 of about 15 nm to about 40 nm, as shown in FIG. 3 to a depth H2 of about 10 nm to about 25 nm, as shown in FIG. 7. In some embodiments, there is no second metal layer in the narrow trench 40b because the first metal layer 55 fills the narrow trench 40b. In some embodiments, the shape of the second metal layer 60 in the wide trench 40a conforms to the shape of the opening in the wide trench 40a after the thermal reflow operation. In some embodiments, an interface between the first metal layer 55 and the second metal layer 60 is not horizontal in a cross-sectional view. In some embodiments, the bottom of the second metal layer 60 in the wide trench 40a is inclined. In some embodiments, a thickness of the second metal layer 60 in the wide trench 40a is thinner at one side than an opposing side in a cross-sectional view. In some embodiments, the second metal layer 60 is substantially triangular-shaped in a cross-sectional view. In some embodiments, the second metal layer 60 contacts the liner layer 50 on one side and is separated from the liner layer by the first metal layer 55 on an opposing side in a cross-sectional view. In some embodiments, the first metal layer 55 fills a greater volume of the wide trench 40a than the second metal layer 60. In some embodiments, the second metal layer 60 fills a greater volume of the wide trench 40a than the first metal layer 55.

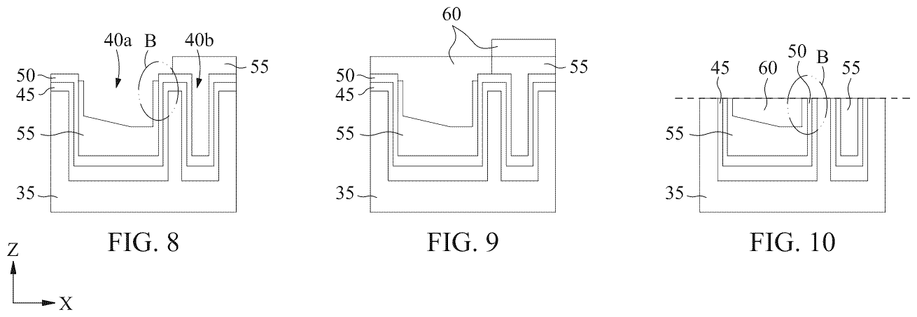

FIGS. 8-11D show detailed cross-sectional views of stages of a method of manufacturing a semiconductor device according to another embodiment of the disclosure. To simplify the disclosure, the semiconductor device component region 20, etch stop layer 25, and the substrate 10 are not shown in FIGS. 8-11D. It is understood that additional operations can be provided before, during, and after processes shown by FIGS. 8-10, and some of the operations described below can be replaced or eliminated, for additional embodiments of the method. The order of the operations/processes may be interchangeable.

A first metal layer 55 is formed in the structure of FIG. 4B and then a thermal reflow operation is performed as disclosed herein. During the reflow operation, the first metal layer 55 flows along the sidewalls of the liner layer 50 including the sidewall in the pattern dense area B, as shown in FIG. 8. Then a second metal layer 60 is formed over the first metal layer 55, as shown in FIG. 9, and disclosed herein in reference to FIG. 6, including the thermal reflow operation. Then, the structure of FIG. 9 undergoes a planarization operation, such as a CMP operation, as disclosed herein in reference to FIG. 7 to form the structure of FIG. 10. As shown in FIG. 10, in some embodiments, the second metal layer 60 is embedded in the first metal layer 55 between the liner layer 50 sidewalls.

In some embodiments, there is no second metal layer in the narrow trench 40b because the first metal layer 55 fills the narrow trench 40b. In some embodiments, the shape of the second metal layer 60 in the wide trench 40a conforms to the shape of the opening in the wide trench 40a after the thermal reflow operation. In some embodiments, the second metal layer 60 is surrounded by the first metal layer 55 and is not in contact with the liner layer 50. In some embodiments, an interface between the first metal layer 55 and the second metal layer 60 is not horizontal in a cross-sectional view. In some embodiments, the bottom of the second metal layer 60 in the wide trench 40a is inclined. In some embodiments, a thickness of the second metal layer 60 in the wide trench 40a is thinner at one side than an opposing side in a cross-sectional view. In some embodiments, the second metal layer 60 is substantially triangular-shaped in a cross-sectional view. In some embodiments, the first metal layer 55 fills a greater volume of the wide trench 40a than the second metal layer 60. In some embodiments, the second metal layer 60 fills a greater volume of the wide trench 40a than the first metal layer 55.

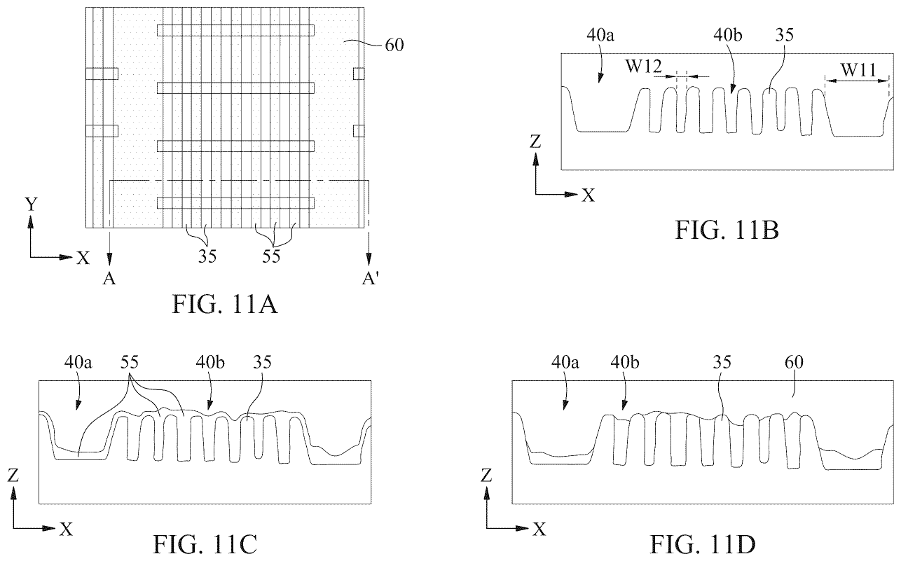

FIG. 11A shows a plan view of a semiconductor device according to embodiments of the disclosure showing an arrangement and wide and narrow metal lines in the interconnect structure. FIGS. 11B, 11C, and 11D show various cross-sectional views of the semiconductor device of FIG. 11A along line A-A′ of FIG. 11A. FIG. 11B shows the arrangement of wide trenches 40a having a width W11 that is wider than the width W12 of the narrow trenches 40b according to some embodiments. FIG. 11C shows the distribution of the first metal layer 55 after the first metal layer 55 is deposited in the trenches, as determined from an elemental analysis technique, such as energy dispersive spectroscopy (EDS) according to some embodiments. As shown in FIG. 11C, in some embodiments, the first metal layer 55 substantially fills the narrow trenches 40b and fills a substantially smaller portion of the wide trenches 40a. In some embodiments, the first metal layer is made of cobalt. FIG. 11D shows the semiconductor device structure after depositing the second metal layer 60 according to some embodiments. In some embodiments, the second metal layer 60 is made of copper. In some embodiments, FIG. 11C depicts the semiconductor device structure after performing the operations disclosed herein in reference to FIG. 5 and FIG. 11D depicts the semiconductor device structure after performing the operations disclosed herein in reference to FIG. 6.

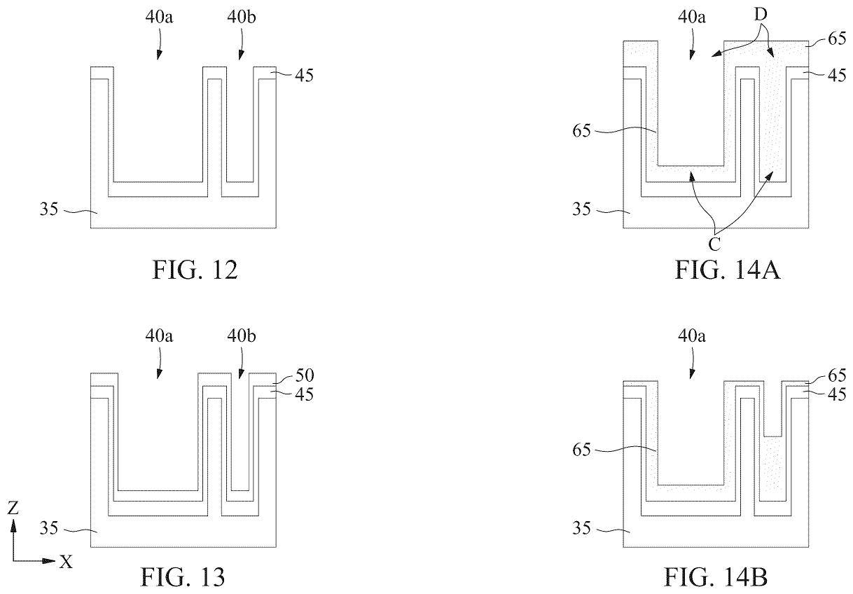

FIGS. 12-16B show detailed cross-sectional views of stages of a method of manufacturing a semiconductor device according to an embodiment of the disclosure. To simplify the disclosure, the semiconductor device component region 20, etch stop layer 25, and the substrate 10 are not shown in FIGS. 12-16B. It is understood that additional operations can be provided before, during, and after processes shown by FIGS. 12-16B, and some of the operations described below can be replaced or eliminated, for additional embodiments of the method. The order of the operations/processes may be interchangeable.

FIG. 12 shows a barrier layer 45 formed over wide trench 40a in a less dense pattern area and a narrow trench 40b in a dense pattern area. The barrier layer 45 is formed of the same materials and by the same techniques as disclosed herein with reference to FIG. 3. The trenches 40a, 40b have same range of dimensions as the trenches disclosed herein with reference to FIG. 3. A liner layer 50 is formed over the barrier layer 45 in some embodiments, as shown in FIG. 13. The liner layer 50 may be formed of the same materials, to the same thickness, and by the same techniques as disclosed herein in reference to FIG. 4A.

A first metal layer 65 is subsequently formed over the first liner layer 50 in some embodiments, as shown in FIGS. 14A and 14B. The first metal layer 65 is formed by CVD in some embodiments using an organic iodide precursor and a metal precursor. In some embodiments, the organic iodide precursor is an alkyl iodide, including C₂H₅I or C₃H₇I. In some embodiments, the first metal layer 65 includes the same metal as the liner layer 50. The metal of the first metal layer 65 and the iodide are co-deposited in some embodiments. Depending on the deposition parameters, the first metal layer 65 may completely fill the narrow trench 40b, as shown in FIG. 14A, or partially fill the narrow trench 40b, as shown in FIG. 14B. In some embodiments, the iodine concentration in the first metal layer is lower near the bottom of the trenches (e.g.-area C) and higher near the tops of trenches (e.g.-area D). In some embodiments, the iodine is thermally driven to the surface of the first metal layer 65 by a hydrogen plasma treatment before forming the second metal layer 60. In some embodiments, the hydrogen plasma includes argon. In some embodiments, the first metal layer 65 includes at least one of ruthenium, cobalt, molybdenum, or tungsten. In some embodiments, the first metal layer is made of ruthenium.

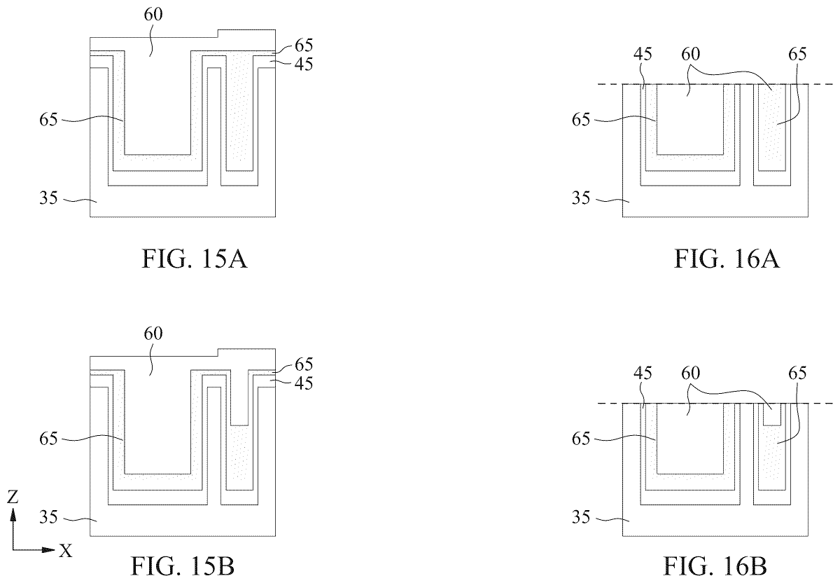

The second metal layer 60 is subsequently formed over the first metal layer 65 in some embodiments, as shown in FIGS. 15A and 15B. The second metal layer is 60 is formed of the same materials and using the same techniques as disclosed herein in reference to FIG. 6, including the thermal reflow operation. As shown in FIG. 15B, a portion of the narrow trench 40b is filled with the second metal layer 60. Then, the structures of FIGS. 15A and 15B undergo a planarization operation, such as a CMP operation, as disclosed herein in reference to FIG. 7 to form the structures of FIGS. 16A and 16B, respectively. As shown in FIG. 16B, in some embodiments, the second metal layer 60 is formed in both the wide trench 40a and the narrow trench 40b. Because the higher iodine concentration portions of the first metal layer 65 are the upper portions of the first metal layer, the CMP operation also removes the higher iodine concentration portions of the first metal layer 65.

In some embodiments, there is no second metal layer in the narrow trench 40b because the first metal layer 65 fills the narrow trench 40b. In some embodiments, the shape of the second metal layer 60 in the wide trench 40a and narrow trench 40b are substantially rectangular in a cross-sectional view. In some embodiments, the thickness of the first metal layer 65 is substantially the same over the sidewalls and the bottom of the wide trench 40a. In some embodiments, the thickness of the first metal layer 65 is greater over the bottom of the wide trench 40 than sidewalls of the wide trench 40a. In some embodiments, the second metal layer 60 is surrounded by the first metal layer 65 and is not in contact with the barrier layer 45 in the wide trench 40a and/or the narrow trench 40b. In some embodiments, the first metal layer 65 fills a greater volume of the narrow trench 40b than the second metal layer 60. In some embodiments, the second metal layer 60 fills a greater volume of the wide trench 40a than the first metal layer 65.

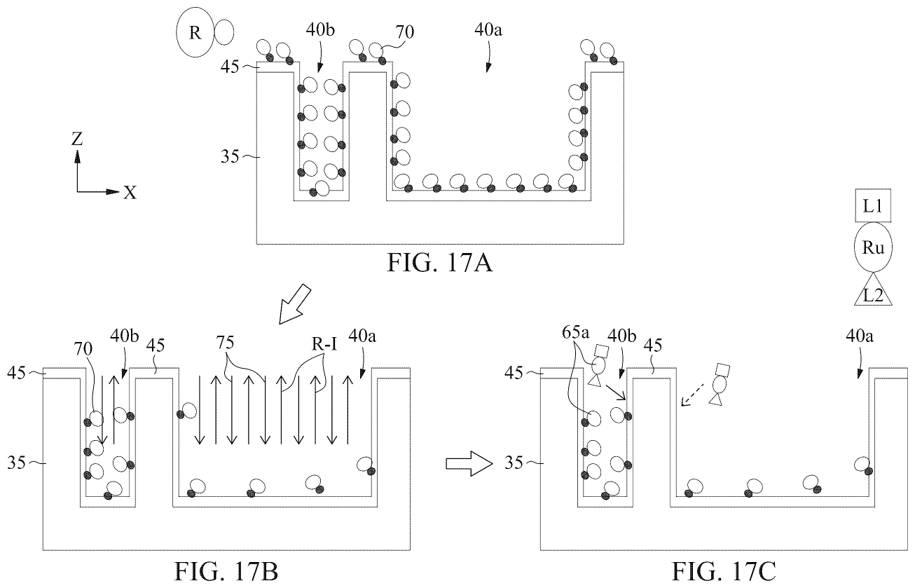

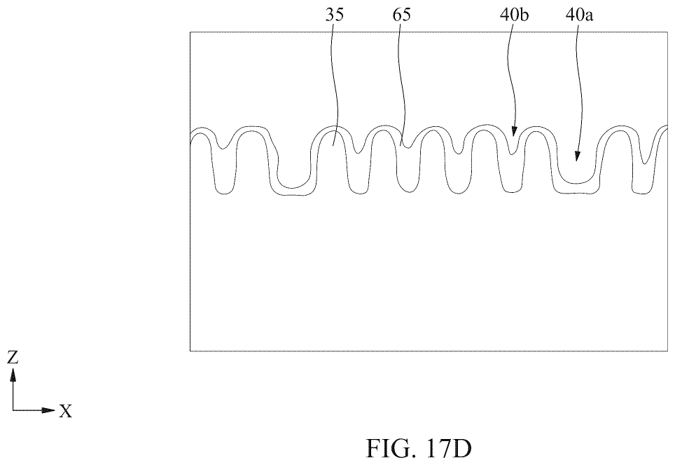

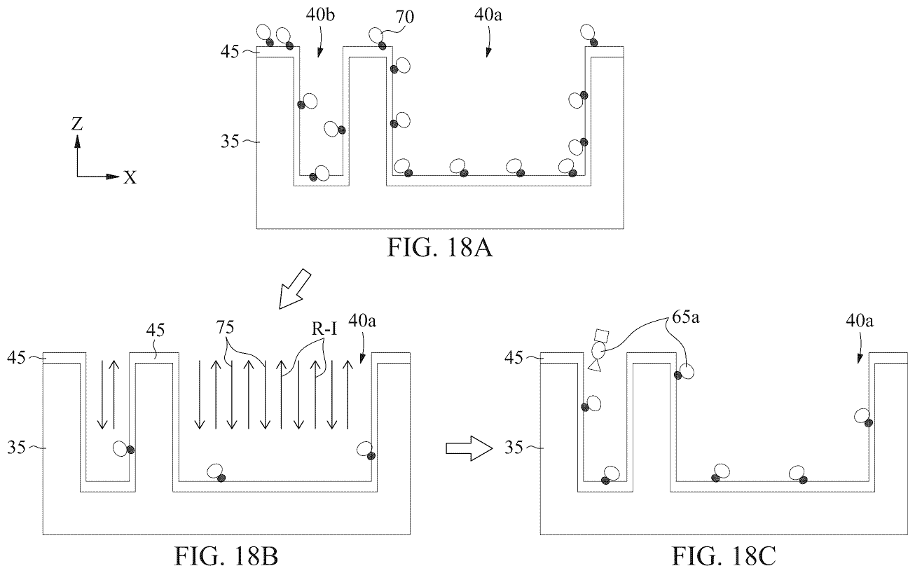

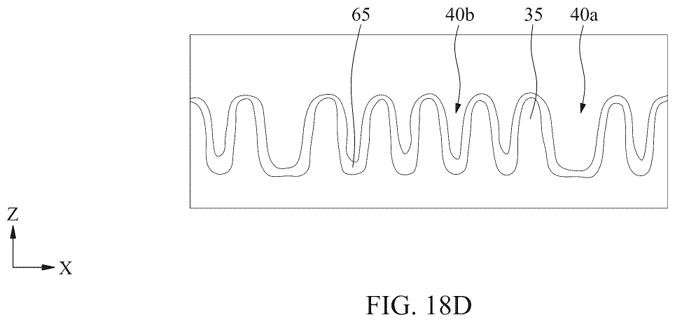

FIGS. 17A-17D and 18A-18D are schematic cross-sectional views of stages of a method of manufacturing a semiconductor device according to embodiments of the disclosure. In some embodiments, the operations shown in FIGS. 16A-17D are used to form the structures shown in FIGS. 12-15B. To simplify the disclosure, the semiconductor device component region 20, etch stop layer 25, and the substrate 10 are not shown in FIGS. 17A-17D and 18A-18D. It is understood that additional operations can be provided before, during, and after processes shown by FIGS. 17A-17D and 18A-18D, and some of the operations described below can be replaced or eliminated, for additional embodiments of the method. The order of the operations/processes may be interchangeable.

In some embodiments, as shown in FIGS. 17A and 18A, an iodide layer 70 is formed over the barrier layer 45 before forming the first metal layer 65. The iodide layer 70 facilitates or catalyzes the growth of a subsequently formed first metal layer 65. The iodide layer 70 may be made of an organic iodide. Suitable organic iodides include alkyl iodides in some embodiments, such as C₂H₅I, C₃H₇I, or C₄H₉I. The iodide layer 70 may be formed by CVD, solvent deposition, or any suitable technique. In some embodiments, the structure of FIG. 12 is soaked in an iodide solution, and the iodide is adsorbed onto the barrier layer 45. In the embodiment of FIG. 17A, a greater amount of iodide is deposited over the barrier layer 45 than in the embodiment of FIG. 18A.

Then, in some embodiments, the iodide layer 70 is subjected to a hydrogen plasma treatment 75, as shown in FIGS. 17B and 18B. The hydrogen plasma treatment removes a portion of the iodide layer. As shown in FIGS. 17B and 18B, the hydrogen plasma treatment 75 is more efficient at removing the iodide layer in the wider trenches 40a or lower density pattern regions. Therefore, a greater percentage of the iodide layer is removed in the wider trenches 40a or lower density pattern regions during the hydrogen plasma treatment 75 than in the narrower trenches 40b or higher density pattern regions. The hydrogen plasma treatment 75 is performed at a higher temperature in the embodiment of FIG. 18B than the embodiment of FIG. 17B. The higher temperature hydrogen plasma treatment removes a greater amount of the iodide layer 70 in the embodiment of FIG. 18B than in the embodiment of FIG. 17B. In some embodiments, the hydrogen plasma treatment in the embodiment of FIG. 17B is performed at a temperature ranging from about 150 °C to about 200 °C. In some embodiments, the hydrogen plasma treatment in the embodiment of FIG. 18B is performed at a temperatures ranging from greater than about 200 °C to about 350 °C and from about 250 °C to about 350 °C in other embodiments. At temperatures outside the disclosed ranges, the iodine removal may be insufficient or too much iodine may be removed.

After the hydrogen plasma treatment, a metal precursor 65a, such as a ruthenium precursor is applied to trench sidewalls and bottom, as shown in FIGS. 17C and 18C. The metal precursor subsequently decomposes to form the first metal layer 65 in some embodiments, as shown in FIGS. 14A, 14B, 17D, and 18D. The first metal layer 65 may be formed of any of the metals disclosed herein for forming the metal layers. In an embodiment, the first metal layer is made of ruthenium. FIGS. 17D and 18D show the distribution of the first metal layer 55 after the first metal layer 55 is deposited in the trenches, as determined from an elemental analysis technique, such as energy dispersive spectroscopy (EDS) according to some embodiments. As shown in FIG. 17D, the first metal layer 55 substantially fills the narrow trenches 40b and fills a substantially smaller portion of the wide trenches 40a. On the other hand, as shown in FIG. 18D, the first metal layer 55 is substantially uniformly deposited in the wide trenches 40a and the narrow trenches 40b.

In some embodiments, the first metal layer is formed by CVD using metal-ligand precursors. In some embodiments, the ligands L1, L2 are an aliphatic or aromatic, cyclic or non-cyclic C2-C30 group, wherein the C2-C30 group is unsubstituted or substituted with one or more selected from the group consisting of —I, -Br, —Cl, -F, —NH₂, —COOH, —OH, -SH, —N₃, —S(═O)—, —CF₃, ═O, —S—, —P-, -PO₂-, -C(═O)SH, —C(═O)O—, —O—, —N—, —C(═O)NH, —SO₂OH, —SO₂SH, —SOH, and —SO₂—, an alkene group, an alkyne group, an imine group, an ether group, an ester group, an aldehyde group, a ketone group, an amide group, a sulfone group, an acetic acid group, a cyanide group, an allene group, an alcohol group, a diol group, an amine group, a phosphine group, a phosphite group, an aniline group, a pyridine group, and a pyrrole group.

In the embodiment of FIGS. 17A-17D, the first metal layer 65 is selectively grown faster in the narrower trenches or higher pattern density regions than the wider trenches or lower pattern density regions, where there is a greater amount of the iodide layer, and the lower temperature hydrogen plasma treatment is performed. Thus, in the embodiment of FIGS. 17A-17D a greater volume percentage of the narrow trenches 40b are filled with the first metal layer 65 than in the wide trenches 40a. On the other hand, in the embodiment of FIGS. 18A-18D, where there is lighter iodide coverage and greater iodide removal during the higher temperature hydrogen plasma treatment, the first metal layer 65 grows at about an equal rate in both the narrow 40b and the wide 40a trenches. In some embodiments, the combined first metal layer 65 and iodide layer 70 formed according to the embodiment of FIGS. 17A-17D includes greater than about 5 at. % iodine, and from about 6 at. % to about 12% at. % iodine in other embodiments. At iodine concentrations outside the disclosed ranges there may be non-optimal first metal layer 65 growth rates and non-optimal second metal layer to first metal layer volume ratios. In some embodiments, the combined first metal layer 65 and iodide layer 70 formed according to the embodiment of FIGS. 18A-18D includes less than about 1 at. % iodine, and from about 0.01 at. % to about 0.9 at. % in other embodiments. In some embodiments, the first metal layer 65 includes ruthenium. At iodine concentrations outside the disclosed ranges, there may not be even first metal layer 65 growth in the narrow and wide trenches 40a, 40b. In some embodiments, a second metal layer 60 is subsequently formed, as disclosed herein in reference to FIGS. 15A and 15B. In some embodiments, the iodine diffuses into the first metal layer 65. A thermal annealing operation may be performed after depositing the first metal layer 65 and/or after forming a second metal layer 60. The thermal annealing operation facilitates diffusion of the iodine throughout the first metal layer.

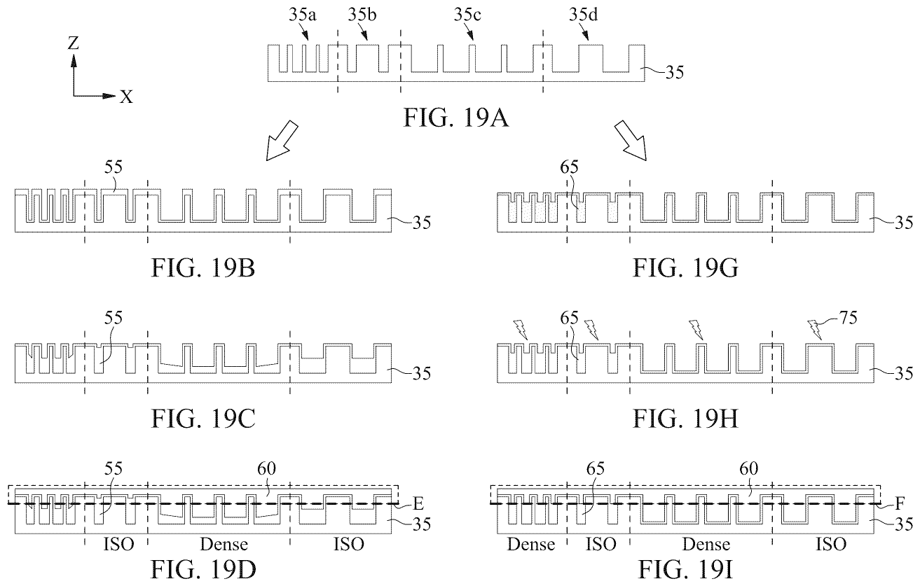

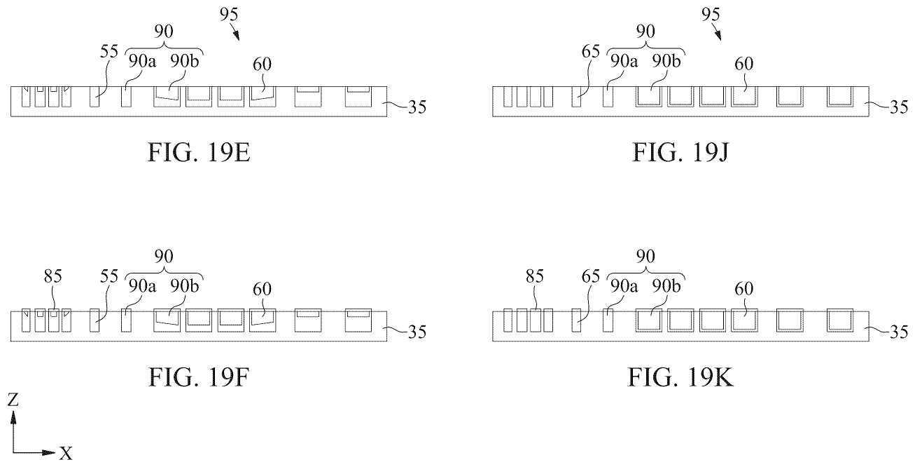

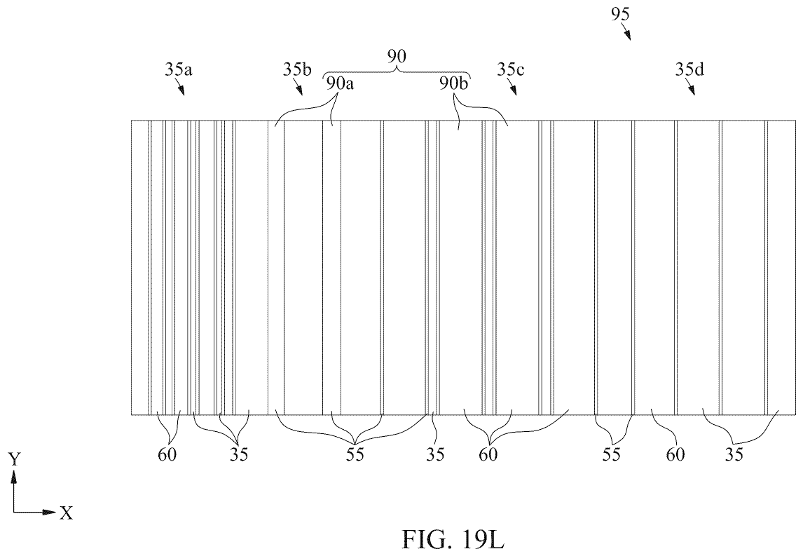

FIGS. 19A-19K show cross-sectional views of stages of a method of manufacturing a semiconductor device according to embodiments of the disclosure. FIGS. 19A-19F illustrate one embodiment of manufacturing a wiring or conductive layer including conductive lines or wirings made of two different metal layers, and FIGS. 19A and 19G-19K illustrate another embodiment of manufacturing the wiring or conductive layer. To simplify the disclosure, the semiconductor device component region 20, etch stop layer 25, and the substrate 10 are not shown in FIGS. 19A-19K. It is understood that additional operations can be provided before, during, and after processes shown by FIGS. 19A-19K, and some of the operations described below can be replaced or eliminated, for additional embodiments of the method. The order of the operations/processes may be interchangeable.

A patterned dielectric layer 35 having various different patterns 35a, 35b, 35c, 35d formed in the patterned dielectric layer 35 is shown in FIG. 19A. The various different patterns 35a, 35b, 35c, and 35d correspond to the different patterns disclosed herein in reference to FIG. 2.

In FIG. 19B a first metal layer 55 is deposited over the patterned dielectric layer. The first metal layer may be deposited by ALD, PVD, CVD, MOCVD, e-beam evaporation, electroplating, electroless plating, or any other suitable technique. In some embodiments, the first metal layer 55 includes at least one of ruthenium, cobalt, molybdenum, tungsten, or copper.

The first metal layer 55 is subjected to a thermal reflow operation in some embodiments, as shown in FIG. 19C. In some embodiments, the thermal reflow operation is performed using infrared heating. In some embodiments, the backside of the semiconductor device structure is exposed to an infrared heating lamp. In other embodiments, the infrared radiation source is an infrared laser. During the thermal reflow, the first metal layer 55 is heated and flows by capillary effect so that first metal layer has a different thickness on the sidewalls of the narrow and wide trenches and in a pattern dense region than a less dense pattern area. In the less dense pattern area a larger amount of the first metal is attached to the sidewall.

Next, a second metal layer 60 is deposited over the reflowed first metal layer 55, as shown in FIG. 19D. The second metal layer 60 may be made of any metal having high conductivity. In some embodiments, the second metal layer 60 is made of copper or a copper alloy. In some embodiments, the second metal layer 60 undergoes a thermal reflow operation as described herein. The structure of FIG. 19D subsequently undergoes a CMP operation to reduce the reduce the height of the structure to the level E, forming conductive lines or wirings 90 in the dielectric layer, including narrow lines 90a and wide lines 90b, as shown in FIG. 19E. In some embodiments, the conductive lines or wirings 90 form an interconnect structure 95. In some embodiments, a cap layer 85 is formed over the conductive lines or wirings, as shown in FIG. 19F. The cap layer is formed of a metal nitride in some embodiments. In some embodiments, the cap layer is made of a tantalum nitride. The cap layer 85 may be formed by any suitable deposition technique disclosed herein and photolithographic patterning techniques.

In another embodiment, the two metal layer conductive lines or wirings are formed by one or more of the operations described herein in reference to FIGS. 13-18E. In FIG. 19G, a first metal layer 65 including iodine is formed. The iodine-containing first metal layer 65 is subsequently subjected to a hydrogen plasma treatment 75 to reduce the amount of iodine in the first metal layer, as shown in FIG. 19H. The hydrogen plasma treatment 75 is performed at a temperature ranging from about 150 °C to about 350 °C, in some embodiments.

Next, a second metal layer 60 is deposited over the reflowed first metal layer 65, as shown in FIG. 19I. The second metal layer 60 may be made of any metal having high conductivity. In some embodiments, the second metal layer 60 is made of copper or a copper alloy. In some embodiments, the second metal layer 60 undergoes a thermal reflow operation as described herein. The structure of FIG. 19I subsequently undergoes a CMP operation to reduce the reduce the height of the structure to the level F, forming conductive lines or wirings 90, including narrow lines 90a and wide lines 90b, in the dielectric layer, as shown in FIG. 19J. In some embodiments, the conductive lines or wirings 90 form an interconnect structure 95. In some embodiments, a cap layer 85 is formed over the conductive lines or wirings 90, as shown in FIG. 19K. In some embodiments, the cap layer 85 is made of cobalt, ruthenium, molybdenum, niobium nitride, a cobalt nitride, a molybdenum nitride, or a tantalum nitride. The cap layer 85 is made of a metal nitride in some embodiments. The cap layer 85 may be formed by a selective CVD process in which the cap layer material would chemisorb on a metal layer, such as Cu, but not on a dielectric layer. For example, a cobalt cap layer is deposited by a selective CVD process using dicarbonylcyclopentadienyl cobalt in some embodiments, and in other embodiments, a cobalt nitride cap layer is depositing using dicarbonylcyclopentadienyl cobalt and an NH₃ plasma. In other embodiments, the cap layer 85 is selectively formed over the metal lines using a blanket deposition, photolithographic patterning, and etching operations.

FIG. 19L is a plan view of the structure shown in FIG. 19E. As shown in FIG. 19L, the metal lines have different pitches in the various pattern areas. For example, the pattern lines 90a in pattern area 35a have a smaller pitch than the pattern lines 90a in pattern area 35b or pattern lines 90b in pattern area 35d. Further, the pattern lines 90b in pattern area 35d have a greater pitch than the pattern lines 90b in pattern area 35c. As shown in FIG. 19L, a density of the metal lines within a first area in plan view is greater than a density of the metal lines within another area of the same size in plan view. For example, the density of metal lines 90a is greater in pattern area 35a than in pattern area 35b (lines 90a) or pattern area 35d (lines 90b). In another example, the density of metal lines 90b in pattern area 35c is greater than the density of metal lines 90b in pattern area 35d.

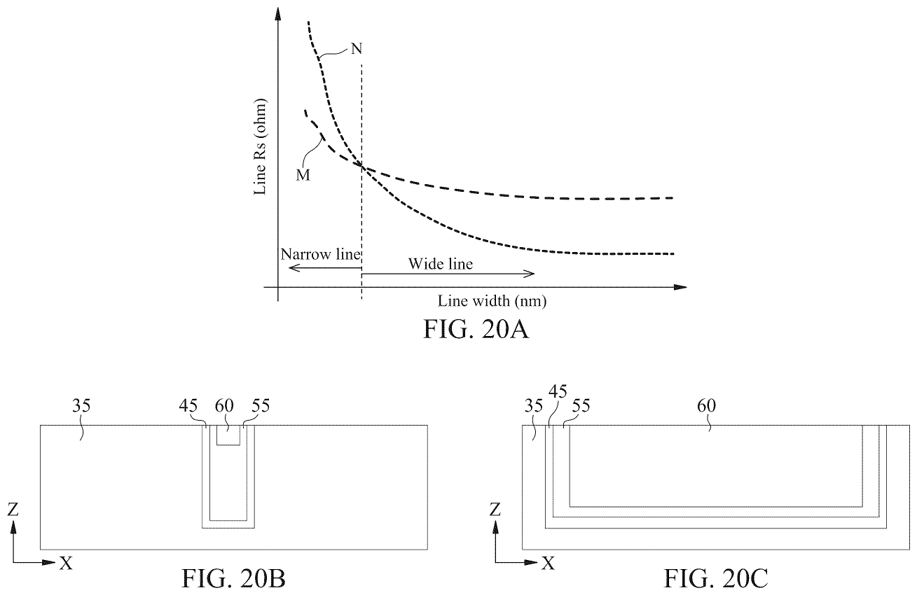

FIG. 20A shows a graph of the line width versus line resistance of metal lines according to embodiments of the disclosure. As shown in FIG. 20A the line resistance of a first metal line M and a second metal line N cross at a line width ranging from about 10 nm to about 25 nm in some embodiments. In an embodiment, the first metal line M and second metal line N cross at about 15 nm. The first metal line M is made of the same material as the first metal layer 55 shown in FIGS. 20B and 20C. The second metal line N is made of the same material as the second metal layer 60 shown in FIGS. 20B and 20C. In some embodiments, the second metal layer 60 is made of a metal that is more conductive than the metal that the first metal layer is made of. Although the second metal line N is made of a metal having a higher conductivity than the first metal line M, in some embodiments, the first metal line is made of a metal having a lower interface resistance and grain boundary resistance than the second metal line material, thus in narrow lines (e.g. −<about 15 nm) the first metal line M has a lower line resistance than the second metal line N. On the other hand, in wider metal lines, the bulk resistance of the metal has a greater effect on the line resistance than the grain boundary resistance and interface resistance. Thus, the wider lines (e.g. −>about 15 nm) of the more conductive second metal layer material have a lower line resistance than the narrower lines made of the lower conductivity first metal line material.

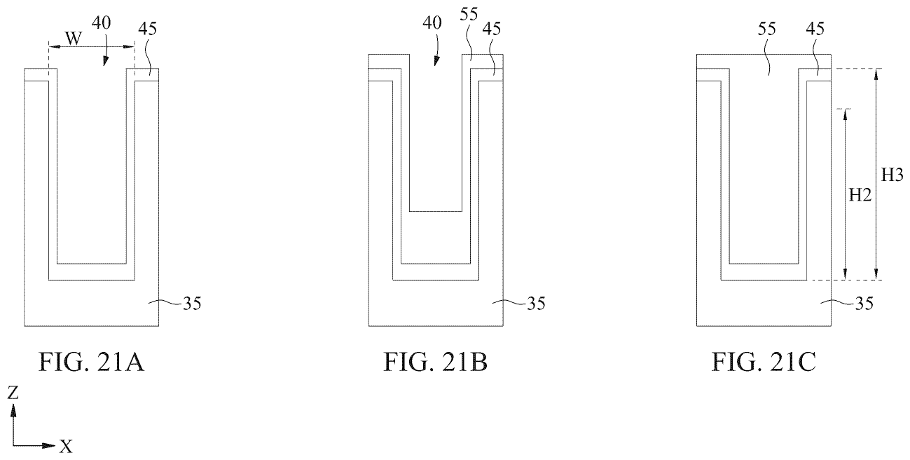

FIGS. 21A-21C show cross-sectional views of stages of a method of manufacturing a semiconductor device according to embodiments of the disclosure. FIG. 21A shows a trench 40 formed in a dielectric layer 35 having a barrier layer 45 formed therein. FIG. 21B shows a first metal layer 55 formed in the trench 40 over the diffusion layer 45. The first metal layer 55 only partially fills the trench 40 in some embodiments, as shown in FIG. 21B. The second metal layer 60 (not shown) is subsequently formed filling the remainder of the trench in FIG. 21B. In other embodiments, the first metal layer 55 fills the entire trench 40 depending on the width of the trench, as shown in FIG. 21C. H2 represents the depth of the trench after the chemical-mechanical polishing operation. H3 represents the height of the first metal layer 55 from the bottom of the trench 40 after any thermal reflow operations.

In some embodiments, a volume ratio of the second metal layer 60 to the first metal layer 55, 65 in a first group of metal lines and a volume ratio of the second metal layer 60 to the first metal layer 55, 65 in the second group of metal lines is different. In some embodiments, the volume ratio of the second metal layer 60 to the first metal layer 55, 65 in wider metal lines is greater than the volume ratio of the second metal layer 60 to first metal layer 55, 65 in narrower metal lines. In some embodiments, the volume ratio of the second metal layer 60 to the first metal layer 55, 65 in the wider metal lines ranges from about 1 to about 10. In some embodiments, the volume ratio of the second metal layer 60 to the first metal layer in the narrower metal lines ranges from about 0.05 to about 0.4. At metal layer volume ratios outside the disclosed ranges the conductivity of the semiconductor device may be lower than the conductivity of semiconductor devices having metal layer volume ratios within the disclosed ranges.

The Table shows a volume ratio of the first metal layer 55 to the second metal layer 60 in the metal line after the chemical mechanical polishing operation for various line widths of the trenches illustrated in FIGS. 21A-21C according to some embodiments. The data in the Table is based on the trenches 40 having a depth of 20 nm after the CMP operation. The volume ratio of the first metal layer decreases with increasing line width.

TABLE
Line Width and Metal Layer Volume Ratio

| | First Metal Layer | Volume Ratio (First |
|---|---|---|
| Line Width | Filling Height | Metal Layer/Second |
| W (nm) | H3 (nm) | Metal Layer) |
| 8 | 23 | 100% |
| 10 | 20 | 100% |
| 12 | 15 | 75% |
| 15 | 12 | 60% |
| 20 | 4 | 20% |
| 30 | 3 | 15% |
| 50 | 3 | 15% |

In some embodiments, metal lines having a width of about 5 nm to about 15 nm are considered narrow metal lines. In some embodiments, the narrow metal lines have volume ratios of the first metal layer 55, 65 to the second metal layer 60 of greater than 90%. In some embodiments, metal lines having a width of about 15 nm to about 40 nm are considered medium metal lines. In some embodiments, the medium metal lines have volume ratios of the first metal layer 55, 65 to second metal layer 60 in the range of about 30% to about 90%. In some embodiments, metal lines having a width of greater than about 40 nm are considered to be wide lines. In some embodiments, the wide metal lines have volume ratios of the first metal layer 55, 65 to the second metal layer of less than 30%.

In some embodiments, the narrow metal lines (e.g. —about 5 nm to about 15 nm width) are made of a metal having a lower electron mean free path (λ) than copper. For example, copper has a λ of about 40 nm. On the other hand, ruthenium has a λ of about 10 nm, cobalt has a λ of about 12, and tungsten has a λ of about 19. The lower λ of the first metal layer metals contributes to the lower line resistance of the narrow metal lines compared to copper lines of the same width according to embodiments of present disclosure.

The methods of forming dual layer metal lines disclosed herein are not limited to forming metal lines. Embodiments of the disclosure include forming conductive vias using the dual metal layer techniques disclosed herein. The techniques disclosed herein may be employed in single damascene and dual damascene methods of forming conductive vias and/or trenches.

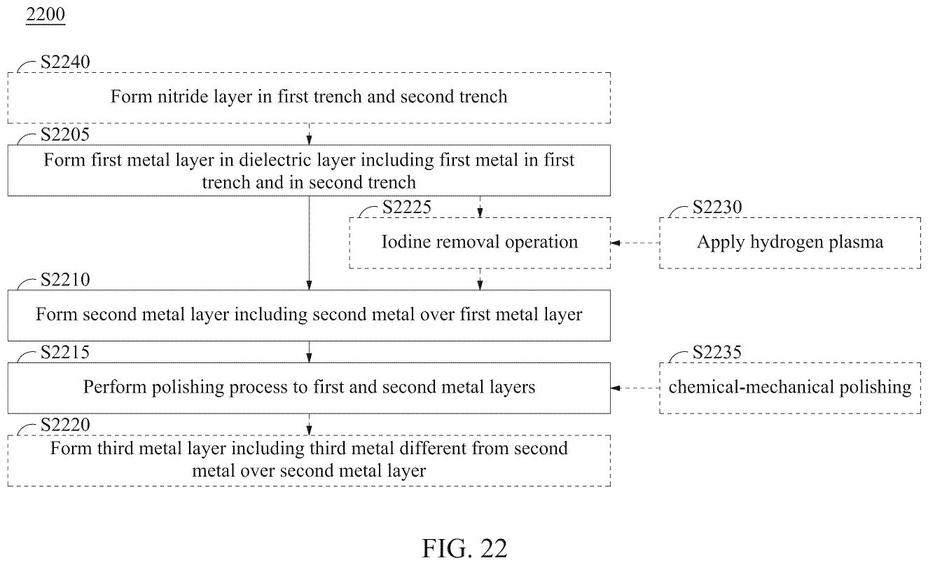

FIG. 22 shows a flow chart for a method 2200 of manufacturing a semiconductor device, including an operation S2205 of forming a first metal layer 55 in a dielectric layer 35 including a first metal in a first trench 40a and in a second trench 40b. In some embodiments, the second trench 40b is narrower than the first trench 40a, and a first thickness of the first metal layer 55 in the first trench 40a is different from a second thickness of the first metal layer in the second trench 40b. In operation S2210, a second metal layer 60 including a second metal is formed over the first metal layer. A polishing process is performed to the first and second metal layers in operation S2215 to form a first metal line in the first trench and form a second metal line in the second trench. The first metal line and the second metal line are spaced apart from one another by the dielectric layer 35. In some embodiments, a third metal layer is formed over the second metal layer in operation S2220. An iodine removal operation S2225 is performed after forming the first metal layer and before forming the second metal layer in some embodiments. In some embodiments, the iodine removal operation S2225 includes an operation S2230 of applying a hydrogen plasma to the first metal layer 55. In some embodiments, the polishing operation S2215 includes a chemical-mechanical polishing operation S2235. In some embodiments, a nitride layer 45 is formed in the first trench and second trench in operation S2240 before forming the first metal layer 55 in the first trench 40A and the second trench 40b.

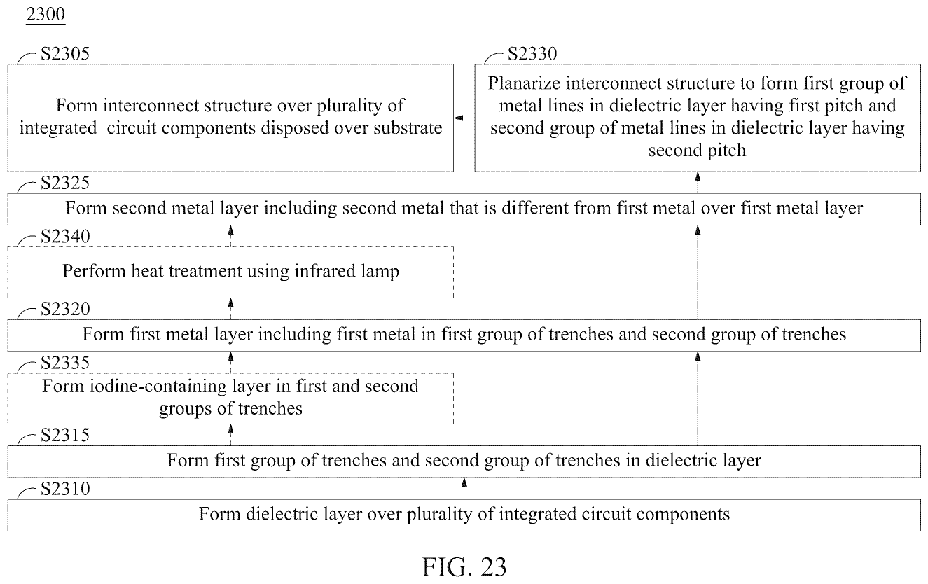

FIG. 23 shows a flow chart for a method S2300 of manufacturing a semiconductor device, including an operation S2305 of forming an interconnect structure over a plurality of integrated circuit components 15 disposed over a substrate 10. The forming the interconnect structure includes an operation S2310 of forming a dielectric layer 30 over the plurality of integrated circuit components 15. A first group of trenches 40a, 40b and a second group of trenches 40a, 40b are formed in the dielectric layer 35 in operation S2315. The first group of trenches has a first pitch and the second group of trenches has a second pitch, and the first pitch and second pitch are different. In operation S2320, a first metal layer including a first metal is formed in the first group of trenches and second group of trenches. A second metal layer 60 including a second metal that is different from the first metal is formed over the first metal layer in operation S2325. In operation S2330, the interconnect structure is planarized to form a first group of metal lines in the dielectric layer having the first pitch and a second group of metal lines in the dielectric layer having the second pitch. A volume ratio of the second metal to the first metal in the first group of metal lines is greater than a volume ratio of the second metal to the first metal in the second group of metal lines. In some embodiments, an iodine-containing layer 70 is formed in the first and second groups of trenches in operation S2335. In operation S2340, a heat treatment is performed on the on the first metal layer 55 using an infrared lamp in some embodiments.

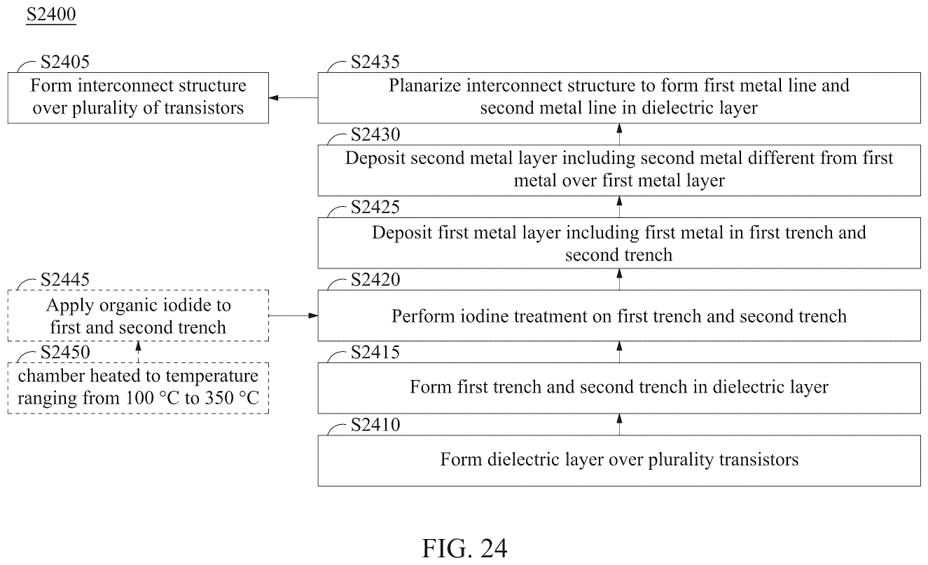

FIG. 24 shows a flow chart for a method S2400 of manufacturing a semiconductor device, including an operation S2405 of forming an interconnect structure over a plurality of transistors 15 disposed over a substrate 10. Forming the interconnect structure includes an operation S2410 of forming a dielectric layer 30 over the plurality of transistors. A first trench 40a and a second trench 40b are formed in the dielectric layer 30 in operation S2415. An iodine treatment is subsequently performed in operation S2420 on the first trench 40a and the second trench 40b. In operation S2425, a first metal layer 65 including a first metal is deposited in the first trench 40a and the second trench 40b after the iodine treatment. In operation S2430, a second metal layer 60 including a second metal different from the first metal is deposited over the first metal layer 65. Then, the interconnect structure is planarized in operation S2435 to form a first metal line and a second metal line in the dielectric layer 35. A volume ratio of the second metal to the first metal in the first metal line is greater than a volume ratio of the second metal to the first metal in the second metal line. In some embodiments, an organic iodide is applied to the first and second trench in operation S2445 during the operation S2420 of performing an iodine treatment on the first and second trench. In some embodiments, the iodine treatment is performed in a chamber heated to a temperature ranging from 100 °C to 350 °C in operation S2450.

Embodiments of the disclosure provide semiconductor devices having reduced metal line resistance and reduced metal line resistance-capacitance. In semiconductor devices with narrow and wide metal lines, embodiments of the disclosure using two metal layer metal lines provide significantly reduced line resistance for narrow metal lines with a limited impact on line resistance of wide metal lines. Thus, overall device performance is improved by embodiments of this disclosure.

It will be understood that not all advantages have been necessarily discussed herein, no particular advantage is required for all embodiments or examples, and other embodiments or examples may offer different advantages.

An embodiment of the disclosure is a method of manufacturing a semiconductor device including forming a first metal layer in a dielectric layer including a first metal in a first trench and in a second trench, wherein the second trench is narrower than the first trench, and a first thickness of the first metal layer in the first trench is different a second thickness of the first metal layer in the second trench. A second metal layer including a second metal is formed over the first metal layer. A polishing process is performed to the first and second metal layers to form a first metal line in the first trench and form a second metal line in the second trench. The first metal line and the second metal line are spaced apart from one another by the dielectric layer. In an embodiment, the first metal has a lower resistance in the second trench than the first metal in the first trench. In an embodiment, the first metal is at least one of cobalt, ruthenium, molybdenum, or tungsten. In an embodiment, the second metal has a lower resistance in the first trench than the second metal in the second trench. In an embodiment, the second metal is different from the first metal and is at least one of ruthenium, cobalt, molybdenum, tungsten, or copper. In an embodiment, the method includes forming a third metal layer comprising a third metal different from the first metal between the dielectric layer and the first metal layer. In an embodiment, the first metal is cobalt, the second metal is copper, and the third metal is ruthenium. In an embodiment, the first metal layer further includes iodine. In an embodiment, the method includes an iodine removal operation. In an embodiment, the iodine removal operation includes applying a hydrogen plasma. In an embodiment, the method includes forming a nitride layer in the first trench and the second trench before forming the first metal layer. In an embodiment, the polishing process is a chemical-mechanical polishing process.

Another embodiment of the disclosure is a method of manufacturing a semiconductor device including forming an interconnect structure over a plurality of integrated circuit components disposed over a substrate. Forming the interconnect structure includes: forming a dielectric layer over the plurality of integrated circuit components and forming a first group of trenches and a second group of trenches in the dielectric layer. The first group of trenches has a first pitch and the second group of trenches has a second pitch, and the first pitch and second pitch are different. A first metal layer including a first metal is formed in the first group of trenches and second group of trenches. A second metal layer including a second metal that is different from the first metal is formed over the first metal layer. The interconnect structure is planarized to form a first group of metal lines in the dielectric layer having the first pitch and a second group of metal lines in the dielectric layer having the second pitch. A volume ratio of the second metal layer to the first metal layer in the first group of metal lines is greater than a volume ratio of the second metal layer to the first metal layer in the second group of metal lines. In an embodiment, the first metal is at least one of cobalt, ruthenium, tungsten, or molybdenum. In an embodiment, the second metal is at least one of ruthenium, cobalt, molybdenum, tungsten, or copper. In an embodiment, the method includes forming an iodine-containing layer in the first and second groups of trenches before forming the first metal layer. In an embodiment, the method includes performing a heat treatment using an infrared lamp after forming first metal layer and before forming the second metal layer. In an embodiment, a density of the second group of metal lines within an area in plan view is greater than a density of the first group of metal lines within a same size area in plan view.

Another embodiment of the disclosure is a method of manufacturing a semiconductor device including forming an interconnect structure over a plurality of transistors disposed over a substrate. Forming the interconnect structure includes: forming a dielectric layer over the plurality of transistors, forming a first trench and a second trench in the dielectric layer, performing an iodine treatment on the first trench and the second trench, depositing a first metal layer including a first metal in the first trench and the second trench after the iodine treatment, depositing a second metal layer including a second metal different from the first metal over the first metal layer, and planarizing the interconnect structure to form a first metal line and a second metal line in the dielectric layer. A volume ratio of the second metal layer to the first metal layer in the first metal line is greater than a volume ratio of the second metal layer to the first metal layer in the second metal line. In an embodiment, the iodine treatment includes applying a an organic iodide to the first and second trench. In an embodiment, the iodine treatment is performed in a chamber heated to a temperature ranging from 100 °C to 350 °C. In an embodiment, the first metal is at least one of cobalt, ruthenium, tungsten, or molybdenum.

Another embodiment of the disclosure is a semiconductor device including a plurality of transistors disposed on a substrate, and an interconnect structure disposed over the plurality of transistors. The interconnect structure includes a dielectric layer is disposed over the plurality of transistors. A first metal line and a second metal line are disposed in the dielectric layer. The first metal line and the second metal line are spaced apart from each other by the dielectric layer. The first metal line and the second metal line include: a first metal layer including a first metal, wherein a first thickness of the first metal layer in the first metal line is less than a second thickness of the first metal layer in the second metal line, and a second metal layer including a second metal different from the first metal disposed over the first metal layer. In an embodiment, the first metal is at least one of cobalt, ruthenium, molybdenum, or tungsten. In an embodiment, the semiconductor device includes a barrier layer disposed between the dielectric layer and the first metal layer. In an embodiment, the barrier layer includes a tantalum nitride. In an embodiment, the second metal is different from the first metal and is at least one of ruthenium, cobalt, molybdenum, tungsten, or copper. In an embodiment, the first metal layer further includes iodine. In an embodiment, a volume ratio of the second metal layer to the first metal layer in the first metal line is greater than a volume ratio of the second metal layer to the first metal layer in the second metal line. In an embodiment, a volume ratio of the second metal layer to the first metal layer in the first metal line ranges from 1 to 10. In an embodiment, a volume ratio of the second metal layer to the first metal layer in the second metal line ranges from 0.05 to 0.4.

Another embodiment of the disclosure is a semiconductor device including an interconnect structure disposed over a plurality of transistor. The plurality of transistors includes a plurality of active regions disposed over a substrate, and an insulating isolation layer disposed between adjacent active regions. The interconnect structure includes a dielectric layer disposed over the plurality of transistors, a first group of metal lines and a second group of metal lines in the dielectric layer, wherein the first group of metal lines and the second group of metal lines include a first metal layer including a first metal and a second metal layer including a second metal different from the first metal. The first group of metal lines has a first pitch and the second group of metal lines has a second pitch different from the first pitch. A volume ratio of the second metal layer to the first metal layer in the first group of metal lines and a volume ratio of the second metal layer to the first metal layer in the second group of metal lines is different. In an embodiment, the first metal is at least one of cobalt, ruthenium, tungsten, or molybdenum. In an embodiment, the second metal is at least one of ruthenium, cobalt, molybdenum, tungsten, or copper. In an embodiment, a density of the second group of metal lines within an area in plan view is greater than a density of the first group of metal lines within a same size area in plan view. In an embodiment, the semiconductor device includes a barrier layer disposed between the dielectric layer and the first metal layer. In an embodiment, the barrier layer includes a tantalum nitride.

Another embodiment of the disclosure is a semiconductor device including an interconnect structure disposed over a plurality of transistors. The interconnect structure includes: a dielectric layer disposed over the plurality of transistors, a first metal line and a second metal line disposed in the dielectric layer, wherein the first metal line and the second metal are spaced apart along a first direction and the dielectric layer is disposed between the first metal line and the second metal line along the first direction. The first metal line and the second metal line include a first metal layer including a first metal and iodine and a second metal layer including a second metal different than the first metal disposed over the first metal layer. A volume ratio of the second metal layer to the first metal layer in the first metal line is greater than a volume ratio of the second metal layer to the first metal layer in the second metal line. In an embodiment, the first metal is at least one of cobalt, ruthenium, tungsten, or molybdenum. In an embodiment, a concentration of iodine in the first metal layer ranges from 0.1 at. % to 10 at. %. In an embodiment, the second metal is at least one of ruthenium, cobalt, molybdenum, tungsten, or copper. In an embodiment, the semiconductor device includes a tantalum nitride barrier layer disposed between the dielectric layer and the first metal layer.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, comprising:
forming a first metal layer in a dielectric layer comprising a first metal in a first trench and in a second trench, wherein the second trench is narrower than the first trench, and a first thickness of the first metal layer in the first trench is different from a second thickness of the first metal layer in the second trench;
forming a second metal layer comprising a second metal over the first metal layer; and
performing a polishing process to the first and second metal layers to form a first metal line in the first trench and form a second metal line in the second trench,
wherein the first metal line and the second metal line are spaced apart from one another by the dielectric layer.

2. The method according to claim 1, wherein the first metal has a lower resistance in the second trench than the first metal in the first trench.

3. The method according to claim 1, wherein the second metal is different from the first metal and has a lower resistance in the first trench than the second metal in the second trench.

4. The method according to claim 3, further comprising forming a third metal layer comprising a third metal different from the first metal between the dielectric layer and the first metal layer.

5. The method according to claim 4, wherein the first metal is cobalt, the second metal is copper, and the third metal is ruthenium.

6. The method according to claim 1, wherein the first metal layer further includes iodine.

7. The method according to claim 6, further comprising an iodine removal operation.

8. The method according to claim 7, wherein the iodine removal operation includes applying a hydrogen plasma.

9. The method according to claim 1, further comprising forming a nitride layer in the first trench and the second trench before forming the first metal layer.

10. The method according to claim 1, wherein the polishing process is a chemical-mechanical polishing process.

11. A method of manufacturing a semiconductor device, comprising:
forming an interconnect structure over a plurality of integrated circuit components disposed over a substrate,
wherein forming the interconnect structure comprises:
forming a dielectric layer over the plurality of integrated circuit components;
forming a first group of trenches and a second group of trenches in the dielectric layer,
wherein the first group of trenches has a first pitch and the second group of trenches has a second pitch, and the first pitch and second pitch are different;
forming a first metal layer including a first metal in the first group of trenches and second group of trenches;
forming a second metal layer including a second metal that is different from the first metal over the first metal layer; and
planarizing the interconnect structure to form a first group of metal lines in the dielectric layer having the first pitch and a second group of metal lines in the dielectric layer having the second pitch,
wherein a volume ratio of the second metal layer to the first metal layer in the first group of metal lines is greater than a volume ratio of the second metal layer to the first metal layer in the second group of metal lines.

12. The method according to claim 11, wherein the first metal is at least one of cobalt, ruthenium, tungsten, or molybdenum.

13. The method according to claim 11, wherein the second metal is at least one of ruthenium, cobalt, molybdenum, tungsten, or copper.

14. The method according to claim 11, further comprising forming an iodine-containing layer in the first and second groups of trenches before forming the first metal layer.

15. The method according to claim 11, further comprising performing a heat treatment using an infrared lamp after forming first metal layer and before forming the second metal layer.

16. The method according to claim 11, wherein a density of the second group of metal lines within an area in plan view is greater than a density of the first group of metal lines within a same size area in plan view.

17. A semiconductor device, comprising:
a plurality of transistors disposed on a substrate; and
an interconnect structure disposed over the plurality of transistors,
wherein the interconnect structure comprises:
a dielectric layer disposed over the plurality of transistors;
a first metal line and a second metal line disposed in the dielectric layer,
wherein the first metal line and the second metal line are spaced apart from each other by the dielectric layer, and
the first metal line and the second metal line comprise:
a first metal layer including a first metal,
wherein a first thickness of the first metal layer in the first metal line is less than a second thickness of the first metal layer in the second metal line; and
a second metal layer including a second metal different from the first metal disposed over the first metal layer.

18. The semiconductor device of claim 17, wherein the first metal is at least one of cobalt, ruthenium, molybdenum, or tungsten.

19. The semiconductor device of claim 17, further comprising a barrier layer disposed between the dielectric layer and the first metal layer.

20. The semiconductor device of claim 17, wherein the first metal layer further includes iodine.
